(19) United States
(12) Patent Application Publication
(10) Pub. No.: US 2007/0069738 A1
(43) Pub. Date: Mar. 29, 2007

(54) Circuit board characteristic impedance inspection method and apparatus

(75) Inventors: Sonic King, Taipei (TW); Bg Fan, Taipei (TW)

Correspondence Address: EDWARDS & ANGELL, LLP, P.O. BOX 55874, BOSTON, MA, 02205, US

(73) Assignee: Inventec Corporation, Taipei (TW)

(21) Appl. No.: 11/390,922

(22) Filed: Mar. 27, 2006

(30) Foreign Application Priority Data
Sep. 27, 2005 (TW) 094133460

(51) Int. Cl. G01R 27/00

(52) U.S. Cl. 324/600

(57) ABSTRACT

A circuit board characteristic impedance inspection method and apparatus is proposed, which is designed for inspecting the characteristic impedance of a circuit board, and which is characterized by the provision of a set of measurement contact points on the circuit board so that during actual inspection, a set of probes can be attached to these measurement contact points for an impedance measurement instrument to measure the characteristic impedance of the circuit board, and then the measured characteristic impedance is compared against a specification value to check if the characteristic impedance meets requirements. This feature allows the manufacturer to conveniently and efficiently inspect whether each manufacturer circuit meets customer-specified requirement in characteristic impedance, and therefore ensures each manufactured circuit board to be reliable to use and quality-assured for shipment to the customer.

### BACKGROUND OF THE INVENTION

1. Field of the Invention

This invention relates to electronics technology, and more particularly, to a circuit board characteristic impedance inspection method and apparatus which is designed for use to inspect the characteristic impedance of a manufactured circuit board, particularly a microwave circuit board, for the purpose of checking whether the characteristic impedance of the circuit board meets a specification value.

2. Description of Related Art

With the advent of wireless technologies, such as wireless networking, mobile phones, GPS (Global Positioning System), etc., the design and manufacture of microwave circuit board is a highly demanded technology in the electronics industry. Fundamentally, microwave circuit boards are provided with microstrips, which are electrically-conductive lines, for conducting extremely high frequency signals, typically in the range from 1 GHz to 3 GHz (gigahertz).

Since a microwave circuit board is used to conduct extremely high frequency signals, the characteristic impedance of the microwave circuit board is an important parameter related to the electrical characteristics of the microwave circuitry on the circuit board. If the characteristic impedance of a microwave circuit board is deviated from its intended value, it will adversely affect the electrical performance of microwave reception, transmission, and demodulation. For this reason, in the manufacture of microwave circuit boards, it is strictly required that each manufactured circuit board precisely meet the specification of characteristic impedance.

Presently in the electronics industry, however, there lacks a settled standard of characteristic impedance measurement between the customer and the manufacturer of microwave circuit boards. For this sake, the characteristic impedances of manufactured microwave circuit boards would usually deviate from customer-specified values. As mentioned above, a microwave circuit board with deviated characteristic impedance will adversely affect the electrical performance of microwave reception, transmission, and demodulation.

### SUMMARY OF THE INVENTION

It is therefore an objective of this invention to provide a circuit board characteristic impedance inspection method and apparatus which is capable of performing an automatic characteristic impedance inspection procedure on each manufactured microwave circuit board for the purpose of checking whether each manufactured microwave circuit board meets the specification of characteristic impedance.

The circuit board characteristic impedance inspection method and apparatus according to the invention is designed for use to inspect the characteristic impedance of a manufactured circuit board, particularly a microwave circuit board, for the purpose of checking whether the characteristic impedance of the circuit board meets a specification value. In practical applications, for example, the circuit board characteristic impedance inspection apparatus of the invention can be integrated to an automatic circuit board production line, so that the circuit board characteristic impedance inspection apparatus of the invention can immediately perform a characteristic impedance inspection procedure on each manufactured circuit board.

The circuit board characteristic impedance inspection method according to the invention comprises: (1) moving and holding the circuit board securely in position on an inspection platform; (2) attaching a set of probes against the measurement contact point and the grounding point on the circuit board; (3) supplying a frequency signal via the probes to the circuit board and measuring the response thereof to thereby determine the characteristic impedance of the circuit board; and (4) comparing the measured characteristic impedance against a specification value to check if the two values substantially match; if YES, issuing a quality pass message; whereas if NO, issuing a quality defect message.

In architecture, the circuit board characteristic impedance inspection apparatus according to the invention comprises: (a) a circuit board fixture module, which is capable of holding the circuit board securely in position on an inspection platform; (b) a probing module, which is capable of being activated when the circuit board is fixed in position on the inspection platform by the circuit board fixture module, and thereupon is capable of attaching a set of probes against the measurement contact point and the grounding point on the circuit board; (c) an impedance measurement instrumentation module, which is capable of being activated when the probes of the probing module have come in contact with the measurement contact point and the grounding point on the circuit board, and thereupon is capable of supplying a frequency signal via the probing module to the circuit board and measuring the response thereof to thereby determine the characteristic impedance of the circuit board; and (d) a quality control module, which is capable of comparing the value of characteristic impedance measured by the impedance measurement instrumentation module against a specification value to check if the two values substantially match; if YES, capable of issuing a quality pass message; whereas if NO, capable of issuing a quality defect message.

The circuit board characteristic impedance inspection method and apparatus according to the invention is characterized by the provision of a set of measurement contact points on the circuit board so that during actual inspection, a set of probes can be attached to these measurement contact points for an impedance measurement instrument to measure the characteristic impedance of the circuit board, and then the measured characteristic impedance is compared against a specification value to check if the characteristic impedance meets requirements. If NOT, the circuit board is considered a defective one and therefore rejected and returned to the production department. In the manufacture of microwave circuit boards, this feature allows the manufacturer to conveniently and efficiently inspect whether each manufacturer microwave circuit meets customer-specified requirement in characteristic impedance, and therefore ensures each manufactured circuit board to be reliable to use and quality-assured for shipment to the customer.

### BRIEF DESCRIPTION OF DRAWINGS

The invention can be more fully understood by reading the following detailed description of the preferred embodiments, with reference made to the accompanying drawings, wherein:

FIG. 1 is a schematic diagram showing a top surface view of a microwave circuit board on which the circuit board characteristic impedance inspection apparatus of the invention is to be utilized for performing a characteristic impedance inspection procedure;

FIG. 2 is a schematic diagram showing the architecture of the circuit board characteristic impedance inspection apparatus according to the invention; and

FIG. 3 is a schematic diagram showing the circuit board characteristic impedance inspection apparatus of the invention during actual operation.

### DETAILED DESCRIPTION OF PREFERRED EMBODIMENTS

The circuit board characteristic impedance inspection method and apparatus according to the invention is disclosed in full details by way of preferred embodiments in the following with reference to the accompanying drawings.

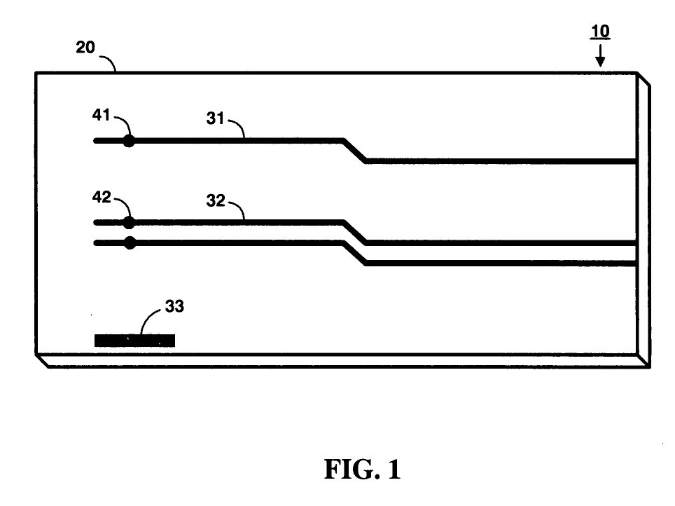

FIG. 1 is a schematic diagram showing a top surface view of a circuit board 10, such as a microwave circuit board, on which the invention is to be utilized for performing a characteristic impedance inspection procedure. As shown, the circuit board 10 is constructed on a substrate 20 which has one side provided with one or more electrically-conductive lines, such as microstirps that are used for conducting microwave signals. In the embodiment of FIG. 1, for example, the electrically-conductive lines include a single-end microstrip 31 and a differential microstrip 32. In addition, the circuit board 10 includes one or more grounding points 33 (Note that the illustration shown in FIG. 1 is only intended for demonstrative purpose; in practice, the circuit board 10 may include many various other electronic components, and the number of microstrips thereon can be much more with complex layout). Moreover, each of the microstrips 31, 32 should be prearranged with measurement contact point 41, 42 at a specified location. For example, the single-end microstrip 31 is prearranged with a measurement contact point 41, while the differential microstrip 32 is prearranged with a pair of measurement contact points 42.

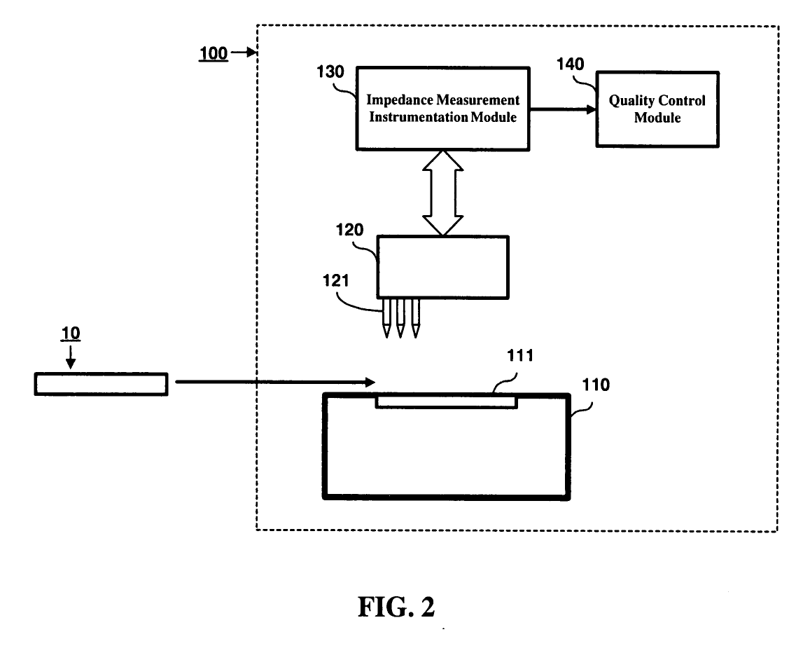

FIG. 2 is a schematic diagram showing the application and modularized component model of the circuit board characteristic impedance inspection apparatus according to the invention (as the part enclosed in the dotted box indicated by the reference numeral 100). As shown, the circuit board characteristic impedance inspection apparatus of the invention 100 is designed for inspecting the characteristic impedance of the circuit board 10 after the circuit board 10 has completed its manufacturing process. In practical implementation, for example, the circuit board characteristic impedance inspection apparatus of the invention 100 can be integrated to an automatic circuit board production line (not shown), so that the circuit board characteristic impedance inspection apparatus of the invention 100 can be used subsequently to perform an automatic characteristic impedance inspection procedure on each manufactured circuit board 10.

As shown in FIG. 2, in architecture, the circuit board characteristic impedance inspection apparatus of the invention 100 comprises: (a) a circuit board fixture module 110; (b) a probing module 120; (c) an impedance measurement instrumentation module 130; and (d) a quality control module 140.

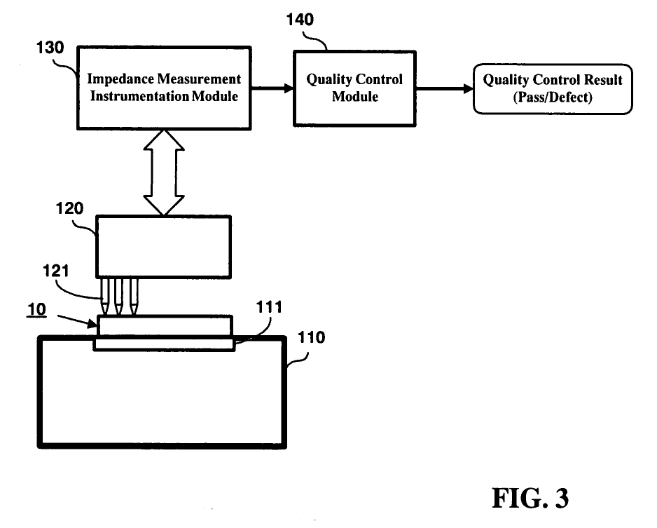

The circuit board fixture module 110, as illustrated in FIG. 3, is capable of holding the circuit board 10 securely in position on an inspection platform 111. In practical implementation, for example, the circuit board fixture module 110 is installed on a test station at the end of a production line (not shown), so that after a batch of circuit board 10 have completed manufacturing process, each manufactured circuit board 10 can be conveyed to the test station (not shown) one by one to undergo an automatic characteristic impedance inspection procedure.

The probing module 120 is capable of being activated when a circuit board 10 is securely fixed in position on the inspection platform 111 by the circuit board fixture module 110, and thereupon capable of moving a set of probes 121 (i.e., electrical contacts) to come in contact with the measurement contact points 41, 42 on the microstrips 31, 32 as well as with the grounding point 33 on the circuit board 10.

The impedance measurement instrumentation module 130 is capable of being activated when the probes 121 of the probing module 120 have come in contact with the measurement contact points 41, 42 and the grounding point 33 on the circuit board 10, and thereupon capable of supplying a frequency signal via the probing module 120 to the circuit board 10 and measuring the response thereof to determine the characteristic impedance (represented by Z₁) of the circuit board 10. The impedance measurement instrumentation module 130 utilizes a conventional instrument and method for measuring the characteristic impedance of the circuit board 10, so detailed description thereof will not be given in this specification.

The quality control module 140 is capable of comparing the value of the measured characteristic impedance Z₁ obtained by the impedance measurement instrumentation module 130 against a specification value Z₀ to check if the two values substantially match. If Z₁=Z₀ or the difference thereof is less than a tolerance value, such as 3%, then the quality control module 140 will issue a quality pass message; and whereas if Z₁≠Z₀ and the difference thereof is greater than the tolerance of 3%, then the quality control module 140 will issue a quality defect message.

The following describes an example of a practical application of the circuit board characteristic impedance inspection apparatus of the invention 100 in actual operation.

Referring to FIG. 1 through FIG. 3 together, in actual application when a production line has finished the fabrication of a batch of circuit boards 10, these circuit board 10 are then conveyed to a test station where the circuit board characteristic impedance inspection apparatus of the invention 100 is installed. As shown in FIG. 3, when one circuit board 10 arrives at the test station, the circuit board characteristic impedance inspection apparatus of the invention 100 is activated, and whereby the circuit board fixture module 110 is activated to move and hold the circuit board 10 securely in position on an inspection platform 111. As the circuit board 10 is securely fixed in position on the inspection platform 111, the probing module 120 is activated to move a set of probes 121 (i.e., electrical contacts) to come in contact with the measurement contact points 41, 42 on the microstrips 31, 32 as well as with the grounding point 33 on the circuit board 10. As the probes 121 of the probing module 120 have come in contact with the measurement contact points 41, 42 and the grounding point 33 on the circuit board 10, the impedance measurement instrumentation module 130 is activated to supply a frequency signal via the probing module 120 to the circuit board 10 and then measure the response thereof to thereby determine the characteristic impedance (represented by Z₁) of the circuit board 10. The measured characteristic impedance Z₁ is then transferred to the quality control module 140, where the measured characteristic impedance Z₁ is compared against a specification value Z₀ to check if the two values substantially match. If Z₁≠Z₀ or the difference thereof is less than a tolerance value, such as 3%, then the quality control module 140 will issue a quality pass message; and whereas if Z₁≠Z₀ and the difference thereof is greater than the tolerance of 3%, then the quality control module 140 will issue a quality defect message. In the case of a quality defect message, the circuit board 10 will be rejected and returned to the production department; whereas in the case of a quality pass message, the circuit board 10 will be transferred to the procedure for shipment to the customer.

In conclusion, the invention provides a circuit board characteristic impedance inspection method and apparatus for inspecting the characteristic impedance of a circuit board, and which is characterized by the provision of a set of measurement contact points on the circuit board so that during actual inspection, a set of probes can be attached to these measurement contact points for an impedance measurement instrument to measure the characteristic impedance of the circuit board, and then the measured characteristic impedance is compared against a specification value to check if the characteristic impedance meets requirements. If NOT, the circuit board is considered a defective one and therefore rejected and returned to the production department. In the manufacture of microwave circuit boards, this feature allows the manufacturer to conveniently and efficiently inspect whether each manufacturer microwave circuit meets customer-specified requirement in characteristic impedance, and therefore ensures each manufactured circuit board to be reliable to use and quality-assured for shipment to the customer. The invention is therefore more advantageous to use than the prior art.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A circuit board characteristic impedance inspection method for inspecting the characteristic impedance of a circuit board, where the circuit board is provided with at least one electrically-conductive line and at least one grounding point, and where at least one measurement contact point is prearranged on the electrically-conductive line;
the circuit board characteristic impedance inspection method comprising:
moving and holding the circuit board securely in position on an inspection platform;
attaching a set of probes against the measurement contact point and the grounding point on the circuit board;
supplying a frequency signal via the probes to the circuit board and measuring the response thereof to thereby determine the characteristic impedance of the circuit board; and
comparing the measured characteristic impedance against a specification value to check if the two values substantially match; if YES, issuing a quality pass message; whereas if NO, issuing a quality defect message.

2. The circuit board characteristic impedance inspection method of claim 1, wherein the circuit board is a microwave circuit board.

3. The circuit board characteristic impedance inspection method of claim 1, wherein the electrically-conductive line on the circuit board includes a single-end microstrip.

4. The circuit board characteristic impedance inspection method of claim 1, wherein the electrically-conductive line on the circuit board includes a differential microstrip.

5. A circuit board characteristic impedance inspection apparatus for inspecting the characteristic impedance of a circuit board, where the circuit board is provided with at least one electrically-conductive line and at least one grounding point, and where at least one measurement contact point is prearranged on the electrically-conductive line;
the circuit board characteristic impedance inspection apparatus comprising:
a circuit board fixture module, which is capable of holding the circuit board securely in position on an inspection platform;
a probing module, which is capable of being activated when the circuit board is fixed in position on the inspection platform by the circuit board fixture module, and thereupon is capable of attaching a set of probes against the measurement contact point and the grounding point on the circuit board;
an impedance measurement instrumentation module, which is capable of being activated when the probes of the probing module have come in contact with the measurement contact point and the grounding point on the circuit board, and thereupon is capable of supplying a frequency signal via the probing module to the circuit board and measuring the response thereof to thereby determine the characteristic impedance of the circuit board; and
a quality control module, which is capable of comparing the value of characteristic impedance measured by the impedance measurement instrumentation module against a specification value to check if the two values substantially match; if YES, capable of issuing a quality pass message; whereas if NO, capable of issuing a quality defect message.

6. The circuit board characteristic impedance inspection apparatus of claim 5, wherein the circuit board is a microwave circuit board.

7. The circuit board characteristic impedance inspection apparatus of claim 5, wherein the electrically-conductive line on the circuit board includes a single-end microstrip.

8. The circuit board characteristic impedance inspection apparatus of claim 5, wherein the electrically-conductive line on the circuit board includes a differential microstrip.
